(19) United States
(12) Patent Application Publication
(10) Pub. No.: US 2013/0192662 A1
(43) Pub. Date: Aug. 1, 2013

(54) Paired Photovoltaic Cell Module

(71) Applicant: Scuint Corporation, Austin, TX (US)

(72) Inventor: Steven B. Snidow, Austin, TX (US)

(73) Assignee: SCUINT CORPORATION, Austin, TX (US)

(21) Appl. No.: 13/753,491

(22) Filed: Jan. 29, 2013

Related U.S. Application Data
(60) Provisional application No. 61/592,550, filed on Jan. 30, 2012.

(51) Int. Cl. H01L 31/052; H01L 31/042

(52) U.S. Cl. CPC H01L 31/0522; H01L 31/042
USPC 136/246; 136/244

(57) ABSTRACT

A photovoltaic module comprised of one or more single-sided or double-sided photovoltaic cells that are angled to the source of energy (i.e., the Sun) and that may include a reflector.

### CROSS-REFERENCE TO RELATED APPLICATIONS

This application claims the benefits of the filing of U.S. Provisional Patent Application Ser. No. 61/592,550 entitled, Paired Photovoltaic Cell Module, filed Jan. 30, 2012 and the specification thereof is incorporated herein by reference.

### STATEMENT REGARDING FEDERALLY SPONSORED RESEARCH OR DEVELOPMENT

Not Applicable.

### REFERENCE TO SEQUENCE LISTING, A TABLE, OR A COMPUTER PROGRAM LISTING COMPACT DISK APPENDIX

Not Applicable.

### TECHNCIAL FIELD

The present invention is in the technical field of photovoltaic devices. More particularly, the present invention is in the technical field of photovoltaic (solar) cells and panels (modules).

### BACKGROUND OF THE INVENTION

Conventional design of solar cells is for solar cells to be a flat, thin parallelogram treated in a manufacturing process to provide for the generation of electricity through the photovoltaic effect. Conventional use of solar cells is to arrange individual solar cells into an array affixed and enclosed in a photovoltaic panel and in which all the individual cells have photo-active sides oriented in the same direction. The array of solar cells form a plane whose cumulative photovoltaic effect is to produce electrical current and that is normally maximized when the solar cell array, the solar panel, faces toward a direct source of light, such as the sun, and at a perpendicular angle. When a solar panel is not perpendicular to a light source the production of electrical current is typically reduced.

To improve the production of electrical current, alternative approaches have been taken to assist in the gain of light by individual, or grouped, photovoltaic cells and whole panels. These alternative approaches are normally characterized by means of solar reflectors and concentrators, such as parabolic mirrors and thin sheets of reflective material. Typically, these concentrating and reflecting devices are additional to the cell or panel and may be directly, or indirectly, connected to one, or more, photovoltaic cells or panels. The below patents provide insight to many such designs and related concepts.

U.S. Pat. No. 8,039,777 (Lance et al; Oct. 18, 2011) teaches us of a solar collector with compound curvature. This patent utilizes an overall trough design with photovoltaic cells raised above the trough and wherein the trough is comprised, essentially, of two curved reflectors on either side of the string of photovoltaic cells. The trough design provides for a large amount of reflected light to be concentrated onto the raised solar cells that are positioned at such an angle as to absorb the light from the reflector resulting in an inverted and angled position to the reflector. This patent utilizes two rows of photovoltaic cells for energy creation with each consisting of a single plane of cells with one photo-active side each.

U.S. Pat. No. 6,119,986 (Stribling, Jr.; Sep. 19, 2000) teaches us of an approach to provide a solar reflector construction from thin-film materials and with more noted application for use with spacecraft. The patent claims various aspects of using thin film sheets as a reflector for a flat photovoltaic panel and in which the reflector sheets are typically hinged to a photovoltaic panel such that the reflector sheets may be unfurled and positioned at an approximate forty-five degree angle to panel and such that the two reflector sheets form a loose “V” shape reflecting the light inward to the panel.

U.S. Pat. No. 4,604,494 (Shepard, Jr.; Aug. 5, 1986) teaches us of a photovoltaic cell array with light concentrating reflectors and relies on a reflector that is utilized to concentrate light onto a photovoltaic cell that is oriented in an inverted, or near inverted, position to the reflector such that the light collecting face of the cell is pointed generally downward. The Shepard invention utilizes a grid approach with individual reflectors, of a general parabolic shape, associated to single photovoltaic cells and in such a way that each pairing works to form a grid-patterned array. This patent relies on individual reflectors paired with individual photovoltaic cells and in which the light striking the cell strikes one, photo-active, side.

U.S. Pat. No. 4,597,377 (Melamed, Jul. 1, 1986) teaches us of a solar reflector system comprised of an elongated system that is generally oriented east-west and is comprised, essentially, of two long reflecting sheets that are slightly concave that act to reflect, if not also concentrate, light onto a surface comprised of a solar receptor (e.g., photovoltaic cells or panels). One key element of distinction is that the Melamed invention has the solar receptor at the bottom, or apex, of the reflectors and forming a loose “V” shape. This patent reflects light onto a single planar surface comprised of one, photo-active, side of a plurality of photovoltaic cells.

U.S. Pat. No. 4,830,038 (Anderson et al; May 16, 1989) teaches us of a photovoltaic panel that is more characteristic of many solar panels and comprised, generally, of a photovoltaic cell, transparent sheet, or sheets, a backing sheet and frame and in which backing sheet and frame are shown in this patent as an elastomer encapsulation acting as both backing sheet and frame and holding all other components together. The photovoltaic cell, or cells, is arranged with the photo-active side oriented to the transparent sheet(s). The photovoltaic panel shown in the patent is also typical of many, similar, panel designs reflecting a layered strata of components resulting in a generally thin and flat panel. As is typical in such panel designs, the panel itself does not contain reflector material and, instead, may rely on devices as discussed in the above patents to assist in the reflection, and concentration, of light onto the flat photovoltaic panel.

U.S. Pat. No. 6,410,843 (Kishi et al; Jun. 25, 2002) teaches us of a solar cell module that consists of a front transparent surface, a rear surface and a plurality of two-sided incidence photovoltaic cells and a reflecting surface all sealed between the front and back surfaces. This patent describes one use of a two-sided cell that is placed into the module with other two-sided cells such that the cells are effectively suspended between the surfaces and laterally spaced from each other thus allowing light to strike the upward face of each flat photovoltaic cell while simultaneously allowing light to pass through the spacing between the cells, be reflected from the reflector surface and striking the bottom photo-active side of the two-side photovoltaic cell(s). This patent differs from the above listed patents in that it utilizes the vertical axis of the photovoltaic panel (module) and incorporates the reflecting material within the panel structure. This patent is similar to the typical photovoltaic panel construction in utilizing the photovoltaic cells in a horizontal only orientation (i.e., flat).

U.S. Pat. No. 5,538,563 (Finkl; Jul. 23, 1996) teaches us of a solar energy concentrator apparatus for bifacial photovoltaic cells. Finkl shows two derivative designs in the invention. The first design is a “V” reflector wherein the “V” shape is elongated and also repeated to form, in essence, a corrugated substrate. At the bottom apex of each “V” a vertical (i.e., positioned at a 90-degree angle) a bifacial photovoltaic cell is placed onto the substrate and such the light striking the 45-degree arms of the “V” reflector provide light to both sides of the bifacial photovoltaic cell. Finkl demonstrates a second design on which the bifacial photovoltaic cell is positioned flat (i.e., at zero degrees) and such that one side receives direct sunlight and the second, downward facing, side receives reflected light from one half of the “V” shaped substrate. This patent has obvious utility and while using two sides of a cell for energy production relies on a high ratio of reflector material to bifacial solar cell.

### SUMMARY OF THE INVENTION

The present invention is a photovoltaic module consisting of one, or more, single-sided or double-sided photovoltaic cells that are each angled to the source of light and, for double-sided photovoltaic cells, are also angled to a back substrate which may also act as a light reflector. The photovoltaic cells may be standalone or grouped and interconnected electrically in series, parallel or in combination.

The primary objective of the present invention is to provide increased electricity generation from a photovoltaic panel (module) as compared to a traditional, flat, photovoltaic panel of the same x-axis and y-axis dimensions.

The primary advantage of the present invention is to provide for increased electrical current from a photovoltaic panel, module or device for the same cost of panel packaging materials and related install costs and resulting in a lower cost per watt for installed photovoltaic generated electricity as compared to traditional flat panels of comparable size and configuration.

An additional advantage of the present invention is to provide for reduced installation time on a per watt basis.

Still another advantage of the present invention is to reduce the per watt transportation and handling costs of the photovoltaic panel (module).

Other objects, advantages and novel features, and further scope of applicability of the present invention will be set forth in part in the detailed description to follow, taken in conjunction with the accompanying drawings, and in part will become apparent to those skilled in the art upon examination of the following, or may be learned by practice of the invention. The objects and advantages of the invention may be realized and attained by means of the instrumentalities and combinations particularly pointed out in the appended claims.

### BRIEF DESCRIPTION OF THE SEVERAL VIEWS OF THE DRAWING

FIG. 1 is an exploded perspective view of a typical photovoltaic module;

FIG. 2 is a perspective view of a double-sided photovoltaic cell;

FIG. 3 is an exploded perspective view of the present invention;

FIG. 4 is a partially exploded perspective view of components of the present invention;

FIG. 5 is a cross-sectional view of one embodiment of the present invention;

FIG. 6 is a partially exploded perspective view of the present invention embodiment shown in FIG. 5;

FIG. 7 is a multi-part diagram reflecting one additional embodiment of the present invention and demonstrating how elements of the present invention are combined;

FIG. 8 is a multi-part diagram reflecting another, and additional, embodiment of the present invention and demonstrating how elements of the present invention are combined.

### DETAILED DESCRIPTION OF THE INVENTION

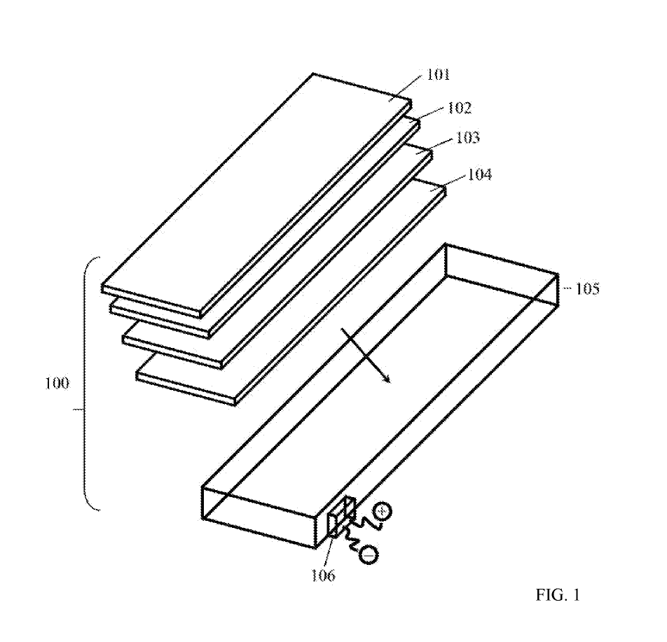

Referring to FIG. 1, a typical photovoltaic panel (module) 100 is shown that is comprised of stacked elements including transparent cover 101, anti-reflective material (coating) 102, a plurality of photovoltaic cells arranged on a plane 103, a back substrate 104 that are all enclosed in solid fame 105. Module 100 is shown to have an electrical interconnect 106 that, for the purposes of illustration, may represent any additional electrical component such as a transformer, inverter or similar device.

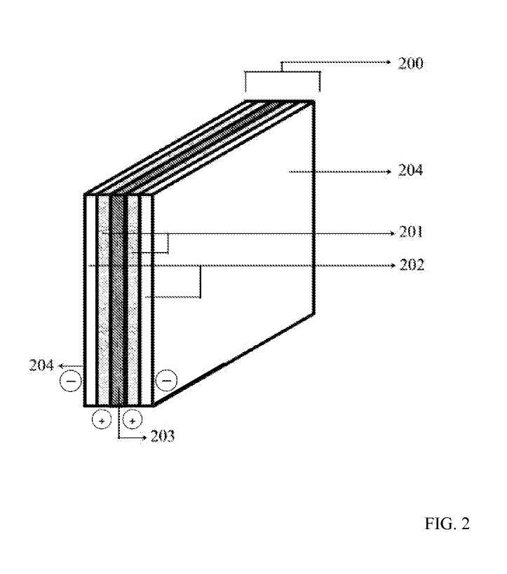

Referring now to FIG. 2, a double-sided photovoltaic cell 200 and in which the double-sided photovoltaic cell 200 is comprised of two individual photovoltaic cells 204 each with p-type material 201 and n-type material 202 and separated by an electrical insulator 203.

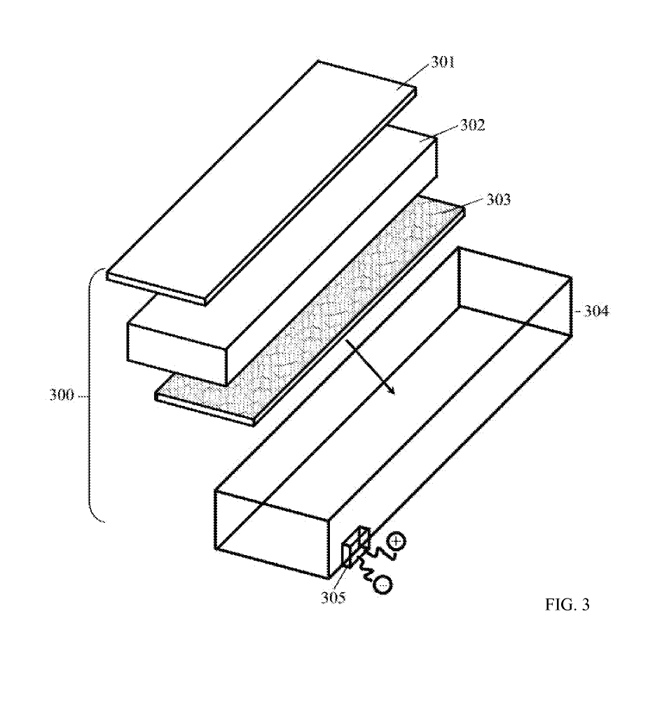

Referring now to FIG. 3 that is the first representation of the present invention, a photovoltaic module 300 is shown to be comprised of a transparent cover 301, a section of double-sided photovoltaic cells 302 and a back substrate 303. It should be understood that module 300 may be comprised of one, or more, double-sided photovoltaic cells and that section 302 may represent only the double-sided cell(s) or such cells with a construct, such as a wire frame, to hold such cells and that back substrate 303 may have a reflective coating. Components 301, 302 and 303 are contained within solid frame 304. For the further purpose of illustration, a generic electrical interconnect 305 is shown and may represent any electrical device such as a transformer, inverter or similar.

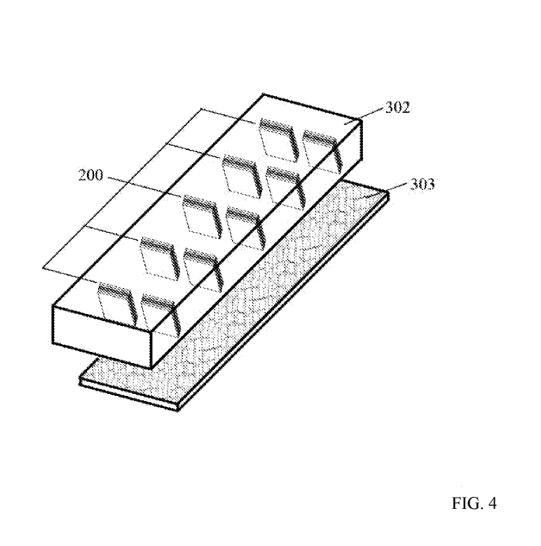

Referring now to FIG. 4, a more detailed view of key elements of the present invention demonstrated in FIG. 3 are now shown with the section of double-sided photovoltaic cells 302 containing a plurality of double-sided photovoltaic cells 200 placed at an angle to the back substrate 303. Back substrate 303 may be understood to be reflective.

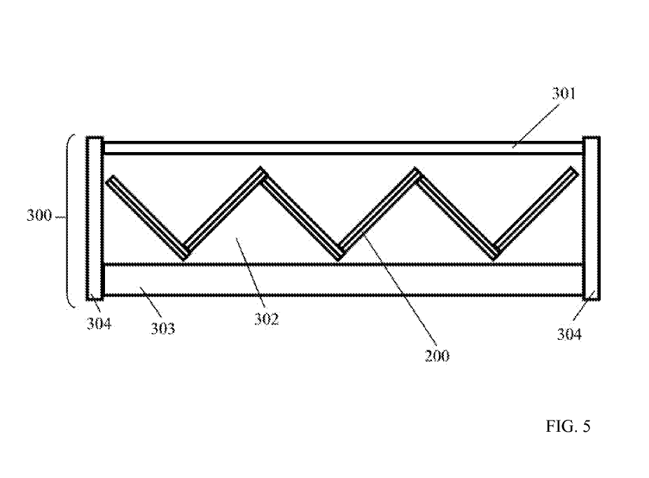

Referring now to FIG. 5, photovoltaic module 300 is shown in a cross-sectional view and comprised of a transparent cover 301, a back substrate 303 and solid frame 304. Double-sided photovoltaic cells 200 are placed abutted one to another and at alternating angles resulting in an overall corrugated effect of the photovoltaic cells. The placement of double-sided photovoltaic cells 200 is within the section of double-sided photovoltaic cells 302.

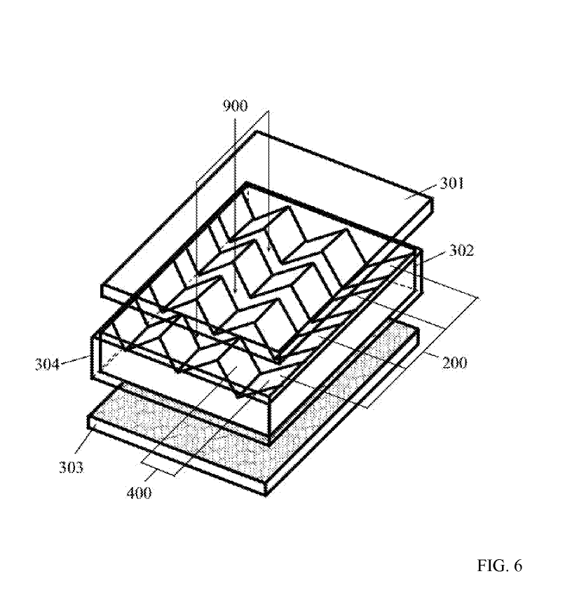

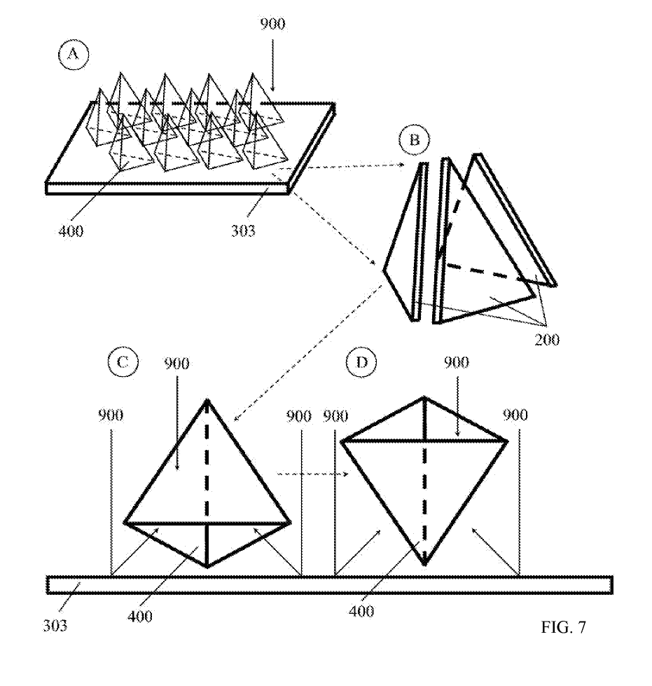

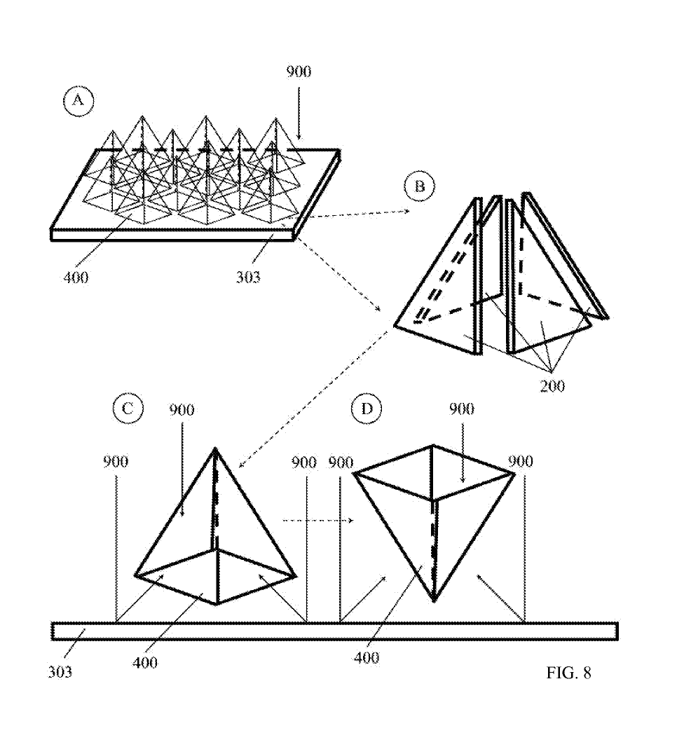

Referring now to FIG. 6, a partially exploded perspective view of elements of the photovoltaic module depicted in FIG. 5 is now shown and for additional illustrative purposes. A plurality of double-sided photovoltaic cells 200 are shown to be first grouped into geometric photovoltaic cell shapes 400 and shown here as a simple pairing of two double-sided photovoltaic cells resulting in a “V” shape. It should be understood that double-sided photovoltaic cells 200 can be arranged into other geometric shapes, or configurations, 400 as shown in FIG. 7 and FIG. 8. Referring back to FIG. 6, the plurality of double-sided photovoltaic cells 200 and subsequent geometric photovoltaic cell shapes 400 are contained within the photovoltaic section 302 and that may include a wire frame construction. Each of these components are housed within the solid frame 304 and situated above back substrate 303 shown with reflective coating and below transparent cover 301. The double-sided photovoltaic cells 200 are arranged in a saw tooth arrangement and with spacing between each saw tooth arrangement and where spacing is a minimum of 15% the side-to-side (lateral) width of double-sided photovoltaic cells 200. Light 900 may strike the top surface of double-sided photovoltaic cells 200 but, through the spacing between double-sided photovoltaic cells 200, is permitted also to pass to the back substrate 303 where it may be reflected back to the underside of the double-sided cells 200 and for the purposes of additional electricity generation.

Referring now to FIG. 7, geometric photovoltaic cell shapes 400 are shown in different representations A, B, C and D. The geometric photovoltaic cell shapes 400 are now comprised of three triangular double-sided cells and that may be understood to be three double-sided cells with three, or four, edges each and arranged into a geometric shape. In part A of FIG. 7, a plurality of the three double-sided cells are arranged over back substrate 303 and with light 900 shown to strike both the surface of each geometric photovoltaic cell shapes 400 but also the substrate. Part B of FIG. 7 demonstrates that each geometric photovoltaic cell shape 400 is comprised of three double-sided photovoltaic cells 200. Part C of FIG. 7 demonstrates one orientation of a geometric photovoltaic cell shape 400 above back substrate 303 and in which light 900 strikes the outward portion of geometric photovoltaic cell shape 400 and alternatively shown reflecting from 303 to the concave side of geometric photovoltaic cell shape 400. Part D of FIG. 7 shows an inverted orientation of geometric photovoltaic cell shape 400 and in which the concave side is oriented up to capture light 900 directly and the convex side is oriented downward allowing for light 900 to be reflected to it from substrate 303. For the purposes of understanding, all cell groups 400 are constructed of multiple double-sided photovoltaic cells 200 as detailed in FIG. 2 and such that each cell group effectively has twice the surface space as a single-sided cell construction of the same design.

Referring now to FIG. 8, geometric photovoltaic cell shapes 400 are shown in different representations A, B, C and D. The geometric photovoltaic cell shapes 400 are now comprised of four triangular double-sided cells and that may be understood to be four double-sided cells with three, or four, edges each and arranged into a geometric shape. In part A of FIG. 8, a plurality of the four double-sided cells are arranged over back substrate 303 and with light 900 shown to strike both the surface of each geometric photovoltaic cell shapes 400 but also the substrate. Part B of FIG. 8 demonstrates that each geometric photovoltaic cell shape 400 is comprised of four double-sided photovoltaic cells 200. Part C of FIG. 8 demonstrates one orientation of a geometric photovoltaic cell shape 400 above back substrate 303 and in which light 900 strikes the outward portion of geometric photovoltaic cell shape 400 and alternatively shown reflecting from 303 to the concave side of geometric photovoltaic cell shape 400. Part D of FIG. 8 shows an inverted orientation of geometric photovoltaic cell shape 400 and in which the concave side is oriented up to capture light 900 directly and the convex side is oriented downward allowing for light 900 to be reflected to it from substrate 303. For the purposes of understanding, all geometric photovoltaic cell shapes 400 are constructed of multiple double-sided photovoltaic cells 200 as detailed in FIG. 2 and such that each cell group effectively has twice the surface space as a single-sided cell construction of the same design.

Referring to FIG. 7 and FIG. 8, for the purpose of additional understanding, the double-sided cells configured are anticipated to be square, rectangular or triangular in shape and allowing for two edges of each double-sided cell 200 to be placed adjacent to other double-sided cells or cell edges such, that depending on shape, the edges may be flush to one another or overlap. It should further be understood that FIG. 7 and FIG. 8 are, together, meant to help illustrate the progression from pairing two double-sided photovoltaic cells 200, as shown in FIG. 6, to forming geometric photovoltaic cell shapes 400 by means of three, four or more double-sided cells. FIG. 7 and FIG. 8 also demonstrate the principle of all geometric photovoltaic cell shapes 400 being oriented in the same direction as is reflected in part A (all inverted or all non-inverted orientation) of FIG. 7 and FIG. 8 or with alternating orientation as is shown in parts C and D of FIG. 7 and FIG. 8 and with the understanding that cell groups 400 shown in parts C and D can be combined so as to effect an alternating (inverted and non-inverted) pattern.

The advantages of the present invention include, without limitation, the ability to increase the amount of electricity generated within the confines of a solar panel (module) due to the angled mounted of solar photovoltaic cells providing for additional cells to be enclosed within the solar panel (module). This principle is further expanded by utilizing double-sided solar photovoltaic cells whose performance is be further improved by use of a reflector.

In broad embodiment, the present invention is a photovoltaic panel (module or other device) that can create more electricity compared to conventional panels through the more effective utilization of photovoltaic space within a three dimensional enclosure.

### DESCRIPTION OF THE PREFERRED EMBODIMENTS (BEST MODES FOR CARRYING OUT THE INVENTION)

The present invention may be used as a device to generate electricity in fixed or portable situation and should be understood to provide for increased generation of electricity through the photovoltaic effect for a given solar photovoltaic panel (module or device) size as compared to a conventional solar photovoltaic panel of the same size (as measured by X-axis and Y-axis coordinates).

As a preferred embodiment, the present invention is a photovoltaic module comprised of multiple rows of two-sided solar photovoltaic cells raised above a reflector and where the successive rows of two-sided solar photovoltaic cells are angled at alternating angles creating a corrugated pattern. Space is provided between the successive rows of two-sided photovoltaic cells to allow for light to transmit to the reflector and illuminate the bottom, and photoactive side, of the two-sided solar photovoltaic cells and resulting is a higher level of electricity generation as compared to a flat, single-sided, conventional photovoltaic panel of comparable size.

The present invention may be utilized as a substitute to and improvement over current model (flat) solar photovoltaic panels and related devices including small point-of-use panels and larger, residential and commercial grade panels.

### INDUSTRIAL APPLICABILITY

The invention is further illustrated by the following non-limiting examples.

### EXAMPLE 1

The present invention may act in a similar capacity of a traditional solar photovoltaic panel as mounted on the roof of a residence. For purposes of example, the present invention is primarily comprised of a plurality of single-sided solar photovoltaic cells arranged at alternating angles, from the panel back substrate, and affecting an overall corrugated pattern of the solar photovoltaic cells. Such panel design, when comprised of the same solar photovoltaic cell technology as a conventional solar photovoltaic panel, will result in approximately 50% more electricity generation to that of the conventional panel thus allowing three panels of the present invention to provide more electricity to the home owner than four conventional panels and at a reduce cost of installation or that may, alternatively, provide approximately 50% more electricity generation for the same installation costs and footprint of panels on the homeowner's roof.

### EXAMPLE 2

The present invention may act in a similar capacity of a traditional solar photovoltaic panel as mounted on the roof of a residence. For purposes of example, the present invention is primarily comprised of a plurality of double-sided solar photovoltaic cells arranged at alternating angles, from the panel back substrate, and affecting an overall corrugated pattern of the solar photovoltaic cells with spacing between rows of the solar photovoltaic cells. The present invention is further comprised to include a back substrate that is reflective providing a means for light to reach the second-side of the double-sided solar photovoltaic cells. Such panel design, when comprised of the same solar photovoltaic cell technology as a conventional solar photovoltaic panel, will result in approximately 100% more electricity generation to that of the conventional panel thus allowing two panels of the present invention to provide more electricity to the home owner than four conventional panels and at a reduce cost of installation and considerably smaller footprint on homeowner's roof.

### EXAMPLE 3

The present invention may act as a point-of-use solar photovoltaic panel such a smaller panel utilized by a state highway department to power road signs. For purposes of this example, the present invention is primarily comprised of a plurality of double-sided solar photovoltaic cells arranged at alternating angles, from the panel back substrate, and affecting an overall corrugated pattern of the solar photovoltaic cells with spacing between rows of the solar photovoltaic cells. The present invention is further comprised to include a back substrate that is reflective providing a means for light to reach the second-side of the double-sided solar photovoltaic cells. Such panel design, when comprised of the same solar photovoltaic cell technology as a conventional point-of-use solar photovoltaic panel, will result in approximately 100% more electricity generation to that of the conventional panel and providing a smaller overall device for the state highway department to install to power its road signs. The time to install each road sign solar panel will be less due to the improved manageability and handling of the smaller panel. Also, additional panels may be stored within a delivery vehicle as compared to the quantity of conventional point-of-use panels and allowing the state highway department to deliver more panels with the overall impact that more solar photovoltaic panels may be installed thus allowing for lower overall installation costs and for department resources to be otherwise tasked.

The preceding examples can be repeated with similar success by substituting the generically or specifically described parameters and/or operating conditions of this invention for those used in the preceding examples.

While the foregoing written description of the invention enables one of ordinary skill to make and use what is considered presently to be the best mode thereof, those of ordinary skill will understand and appreciate the existence of variations, combinations, and equivalents of the specific embodiment, method, and examples herein. The invention should therefore not be limited by the above described embodiment, method, and examples, but by all embodiments and methods within the scope and spirit of the invention as claimed.

I claim:

1. A photovoltaic module comprised of a plurality of single-sided solar photovoltaic cells that form at least one angled row and that are electrically interconnected in series, parallel or a combination of series and parallel and where the photovoltaic module has electrical interconnects to interconnect to at least one other AC or DC device and where the angle of the row(s) of single-sided solar photovoltaic cells is between 1-89 degrees and where the direction of the single-sided solar photovoltaic cells angle may alter from row to row;

2. A photovoltaic module comprised of a plurality of double-sided solar photovoltaic cells that form an angled row of double-sided solar photovoltaic cells and where rows of double-sided solar photovoltaic cells are separated by a minimum of 15% the lateral width of a single double-sided solar photovoltaic cell and where the double-sided solar cells are electrically interconnected in series, parallel or a combination of series and parallel and where the photovoltaic module has electrical interconnects to interconnect to at least one other AC or DC device and where the angle of the row of double-sided solar photovoltaic cells is between 1-89 degrees and where the direction of the double-sided solar photovoltaic cells angle may alter from row to row;

3. A photovoltaic module comprised of a plurality of double-sided solar photovoltaic cells and in which the solar photovoltaic cells are suspended by any means at an angle between 1-89 degrees above a reflective substrate and where the double-sided solar photovoltaic cells are electrically interconnected in series, parallel or a combination of series and parallel and where the photovoltaic module has electrical interconnects to interconnect to at least one other AC or DC device;

4. A two-sided solar cell device comprised of at least two individual solar cells with photo-active faces set in opposite directions and separated by an electrical insulator and bound together by any means.
